(19) United States
(12) Patent Application Publication
(10) Pub. No.: US 2005/0063363 A1
(43) Pub. Date: Mar. 24, 2005

(54) Communication protocol over power line communication networks

(76) Inventors: Sashi Lazar, Silver Spring, MD (US); James Fisch, Columbia, MD (US); Christopher L. Reinert, Plano, TX (US); Charles Abraham, Clarksville, MD (US)

Correspondence Address: AKIN GUMP STRAUSS HAUER & FELD L.L.P., ONE COMMERCE SQUARE, 2005 MARKET STREET, SUITE 2200, PHILADELPHIA, PA, 19103-7013, US

(21) Appl. No.: 10/679,947

(22) Filed: Oct. 6, 2003

Related U.S. Application Data
(63) Continuation-in-part of application No. 10/666,852, filed on Sep. 19, 2003.

(51) Int. Cl. H04L 12/66; H02J 1/00; H01P 5/12; H03K 17/62

(52) U.S. Cl. 370/352; 333/117; 307/1; 327/407

(57) ABSTRACT

A communication apparatus for high-speed data transmission over power line networks comprises a head-end unit which provides a single logical entry point into the communication network, an infrastructure of physical power line cables, one or more client-end units which communicate with the head-end unit, and one or more hybrid units which simultaneously acts as a head-end unit for another physical sub-network of the power line communication network and functions as a client-end unit of another physical sub-network of the power line communication network.

### CROSS-REFERENCE TO RELATED APPLICATIONS

This application is a continuation-in-part of U.S. Non-Provisional application Ser. No. 10/666,652 filed Sep. 19, 2003 entitled “Communication Protocol over Power Line Communication Networks.”

### BACKGROUND OF THE INVENTION

The present invention relates generally to power line communication networks, and more particularly the protocols used for enabling and transmitting information over electrical power lines.

Typically, a power line communication network (PLC) is composed of two components. The first component is the Wide-Area Power Line Network (WPLN), which is the communication infrastructure that provides transmission of data between the utility substations and customer premise equipment typically located at, or near by, an electric power meter at a customer premise. The second component of the power line communication network is the Local Area Power Line Network (LPLN), which is the communication infrastructure located at the customer premise.

The components of the power line communication network provide one or more a bidirectional communication channels. Each channel is a point-to-point link between a transmitter/receiver pair at one end of a transmission medium, a physical medium which transmits electrical signals, and a second transmitter/receiver pair at a distant end of the transmission medium. To implement a full duplex channel, each transmitter/receiver pair may act as a transmitter and a receiver simultaneously.

In a typical configuration, the customer premise equipment includes a device that includes two transmitter/receiver pairs. A first transmitter/receiver pair communicates over the WPLN with an upstream transmitter/receiver pair located at the utility substation. A second transmitter/receiver pair communicates with all the end-user equipment located at customer premises. In essence, the second transmitter/receiver pair provides a single point of entry into the customer premise LPLN.

In addition of the physical infrastructure, the power line communication network provides a resource allocation scheme that defines the policies and procedures for inserting and removing devices into and from the power line communication network. These resource allocation schemes are typically based on different policies on the WPLN and the LPLN.

### SUMMARY OF THE INVENTION

Briefly stated, the present invention comprises power line communication system for communicating information over a power line grid. The system comprises a first head-end unit and one or more first hybrid units connected to the power line grid. The one or more first hybrid units include a first client-end unit adapted to communicating with the first head end unit, and a second head-end unit adapted to communicating with one or more second client-end units.

### BRIEF DESCRIPTION OF THE DRAWINGS

The foregoing summary, as well as the following detailed description of the preferred embodiments of the invention, will be better understood when read in conjunctions with the appended drawings. For the purpose of illustrating the invention, there are shown in the drawings embodiments that are presently preferred. It should be understood, however, that the invention is not limited to the precise arrangement and instrumentalities shown. In the drawings, like numerals are used to indicate like elements throughout. In the drawings:

FIG. 1 is a graphical illustration of the full-duplex communication channel between a head-end unit and various client-end units.

FIG. 2 is a graphical illustration of a hybrid data transmit and receive unit, which functions as a client-end unit on one sub-network and the head-end unit on another.

FIG. 3. is a flow diagram of device insertion into the power line communication network.

FIG. 4 is a flow diagram of detecting inactive client-end devices.

FIG. 5. is a graphical illustration of a typical power line communication network over AC power lines.

FIG. 6 is a graphical illustration of the frame and packet format used by the power line communication network.

FIG. 7. is a graphical illustration of a typical power line communication network over a DC power line.

### DETAILED DESCRIPTION OF THE INVENTION

The present invention describes both the physical and logical characteristics of a power line communication system.

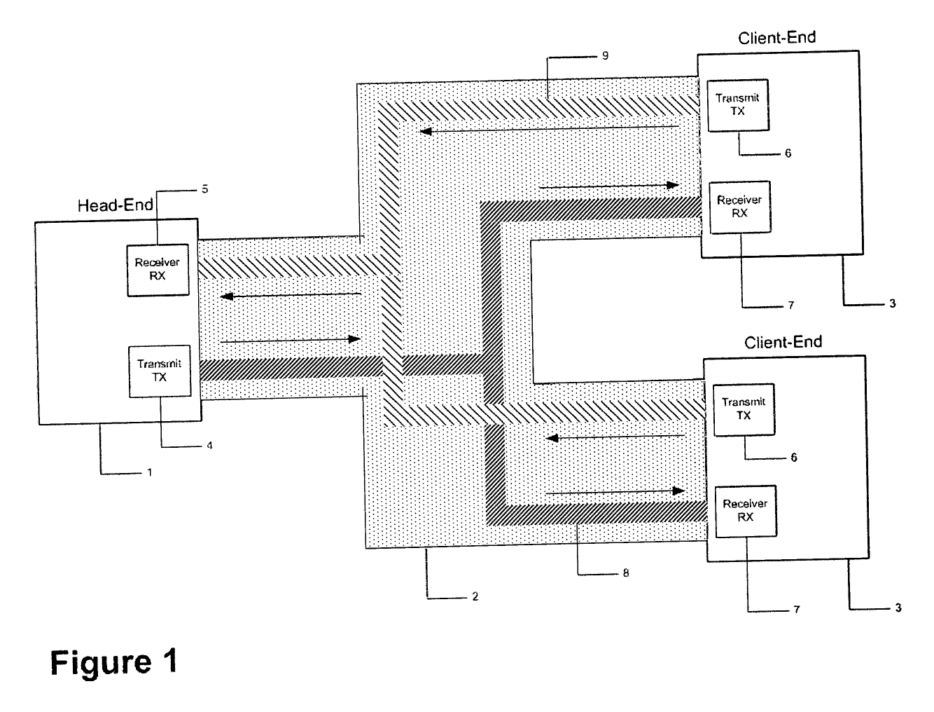

FIG. 1 shows a preferred embodiment of a wide area power line communication network (WPLN) comprising a head-end unit 1, a power line grid 2 and one or more client-end units 3. Although the electrical power grid is typically viewed as a shared bus medium, for the purpose of this invention, based on the nature of the transmission and reception rules, the WPLN is viewed as a point-to-multipoint architecture. At the center of the architecture is the head-end unit 1, which is responsible—among many other things—for supervising access to the resources (i.e. medium access control) for a sub-network. The head-end unit 1 comprises a head-end transmitter module 4 and a head-end receiver module 5, each of which is tuned to different frequency bands, such that the two frequency bands do not overlap, nor do they interfere with one another.

In addition to the head-end unit 1, there is one or more client-end units 3 attached to the WPLN. Although similar in hardware design, the client-end units 3 act as slave devices to the head-end unit 1. Each client-end unit 3 comprises a client-end transmitter 6 and a client-end receiver 7 module, tuned to different frequency bands, such that the two frequency bands do not overlap, nor do they interfere with one another.

From a network topology point of view, there is a logical full duplex communication channel between every client-end unit 3 and an associated head-end unit 1 of the WPLN network. This logical bi-directional communication path is actually composed of two half-duplex channels, one from the head-end unit 1 to each client-end unit 3 (downstream path) 8, and another from each client-end unit 3 to the head-unit 1 (upstream path) 9. These half-duplex channels are implemented by tuning the frequency of the client-end units' receiver module's 7 to the transmit frequency of the head-end unit 1. Similarly, the head-end unit's receiver module 5 is tuned to the exact same frequency as the transmitter module 6 of each of the client-end units 3.

The described dual unidirectional configuration has three advantages. First, the frequency bands in both the downstream and upstream directions are mutually exclusive, unlike typical local area network (LAN) and wide area network (WAN) environments where all the traffic shares the same transmission medium. Therefore the actual total throughput of the WPLN is the sum of the downstream and the upstream communication channel's capacity. Second, given the physical configuration of the network, the downstream communication path is guaranteed to be collision free. This eliminates the need for complex collision detection algorithms. Third, and perhaps most importantly, this frequency division scheme allows multiple head-end units 1 to be placed on the same physical electrical power line grid 2. However, it is important to observe that whereas these head-end units 1 are physically connected to the same power line grid 2, their transmit and receive frequency bands are mutually exclusive, therefore they are separate sub-networks, each with its own set of client-end units 3. More specifically, each client-end unit 3 generally communicates with only the head-end unit 1 associated with its specific sub-network. Nevertheless, this property provides virtually limitless bandwidth over the electrical power line grid 2. As long as the transmit and receive frequencies are mutually exclusive and non-interfering, there are no restrictions on the number of logical sub-networks which can be overlaid on the same physical power line grid 2.

Since on any given (logical) power line communication network there is only a single head-unit 1 with a single transmitter module 4, the downstream path is guaranteed to be collision free. The upstream pipe 9, however, is composed of a single head-end receiver 5 with multiple client-end transmitter modules 6, all tuned to the same transmit frequency. If not carefully synchronized, the transmission of one client-end unit 3 could collide with transmissions by other client-end units 3. To avoid collision on the upstream direction, the total upstream transmission epoch is divided into time slots. Preferably, each time slot has an equal transmit duration and may be assigned to no more than one client-end unit 3 at a time. Being assigned one or more time-slots permits the client-end units 3 to transmit in the upstream direction.

The allocation scheme by which client-end units 3 are assigned their individual time slots varies based on the network environment. In the WPLN network, time slot resources are typically assigned based on a pre-defined subscription rate. Since each time slot provides a fixed amount of channel capacity, time slot allocation of WPLNs is based on the amount of premium paid by each end user. In addition, the preferred embodiment uses a dynamic allocation algorithm, in which resources are (re)calculated and (re)assigned each time a new client-end unit is inserted into the network, or an existing client-end unit is deactivated.

In the LPLN, where most of the devices are under the same administrative domain, unless they belong to a different class of service, bandwidth allocation is typically based on an “equal share” policy. In other respects, the WPLN and LPLN operate identically.

Whereas the time slot based transmission scheme can provide collision free communication for all client-end devices 3 registered with the head-end unit 1, the insertion of new devices, which do not yet have resources allocated to them, pose a challenge because these devices have not received any time slot allocation, and therefore, by the rules of the protocol, are not allowed to transmit data. To facilitate registering new client-end units with the head-end unit, one or more time slots may be reserved by the WPLN and LPLN explicitly for new device registration. It is worth noting here, that registration time slots are prone to occasional collisions, when one or more client-end devices 3 send their registration information to the head-end unit 1 at the same time. However, random timeout and backup algorithms can be used to minimize collisions among new client-end units 3.

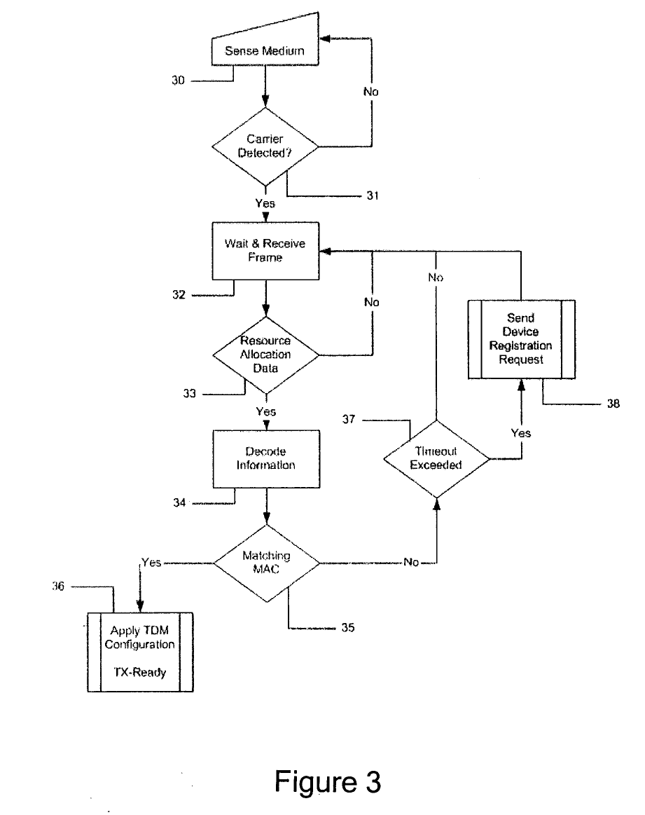

Referring now to FIG. 3, the protocol for new device insertion is shown as follows:
a. the client-end unit 3 continuously monitors 30 the transmission medium, waiting for carrier detection 31;
b. when carrier has been detected, the client-end unit 3 waits for a medium access control (MAC) supervisory packet 32, which contains the broadcasted time slot allocations for all known client-end units 3;
c. upon receiving a MAC supervisory packet, the new client-end unit 3 searches 34 the time slot allocation table for a record that matches its hardware address 35;
d. if a matching record is located, the client-end unit 3 incorporates the time slot allocation record into its memory, and may begin transmitting data in the upstream direction 36. Otherwise if the received MAC supervisory packet does not contain a matching time slot allocation record, the client-unit passively returns to waiting for a new MAC supervisory packet 32, unless the pre-configured timeout expires 37, in which case the client-end unit sends a registration message 38 to the head-end unit 1 over the reserved registration time slots, and passively returns to waiting 32 for a new MAC supervisory packet 32.

It is worth noting here, that the head-end unit 1 may elect to deny the registration request from the client-end unit 3. This is an implicit denial of service, since the head-end unit 1 does not send an acknowledgement downstream to the requesting client-end unit 3. The head-end unit 1 simply does not include a new allocation record in the table of broadcasted time slot allocations.

When a dynamic time slot allocation scheme is used, it is important for the head-end unit 1 to detect when one or more client-end units 3 are inactive, so that the previously allocated time slot resources can be re-assigned to other, active, client-end units.

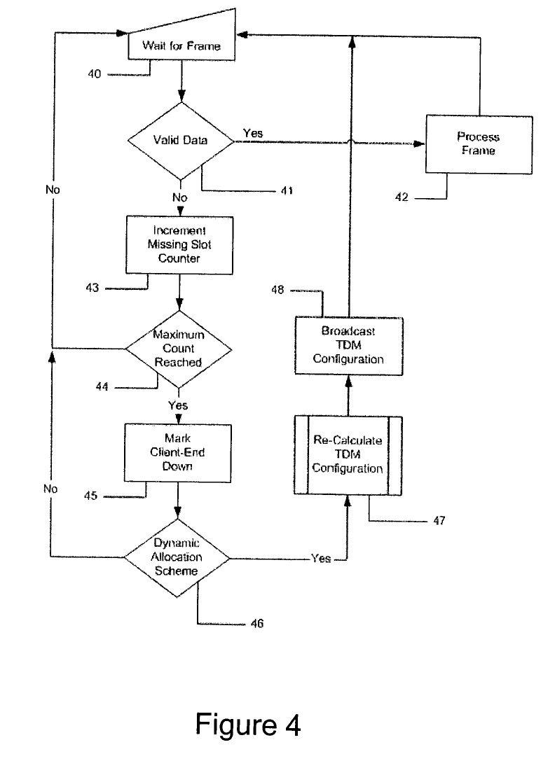

The protocol logic for detecting inactive client-end units 1 is as follows (see FIG. 4):
a. for each upstream time slot, the head-end unit 1 examines the received frame 40 to determine if the transmission contains any valid data 41 (note that client-end units 3 transmit null frames during all their assigned time-slots, even when they have no actual data to transmit);
b. if the time slot does not contain valid data, the missing slot counter is incremented 43 for the client-end device 3 to which the time slot was assigned;
c. if the maximum missing slot count is exceeded, the head-end unit 1 marks the client-end unit as “down” 45, and the client-end unit's resource allocation record is removed 47 from the time slot allocation table broadcast 48 downstream by the head-end unit 1; and
d. if possible, the previously allocated time slots are assigned to other, currently active, client-end units 3.

It is imperative to the correct operation of this scheme that all client-end units 3 use the most up-to-date time slot allocation data sent by the head-end unit 1. Every client-end unit 3 must be ready to receive and update its time slot allocation information based on the MAC supervisory packets broadcast downstream from the head-end unit 1.

The protocol for re-configuring the local time slot allocation information for each client-end unit 3 is as follows:
a. the client-end device 3 continuously monitors the downlink channel for a MAC supervisory packet;
b. if the MAC supervisory packet contains any MAC supervisory information, the client-end unit 3 searches the time allocation table contained in the supervisory packet for a record that matches its own hardware address;
c. if a matching record is found, the time slot allocation record is immediately applied to the client-end unit's local configuration; and
d. if no matching record is found, the client end device immediately ceases transmission, and enters into a reset state.

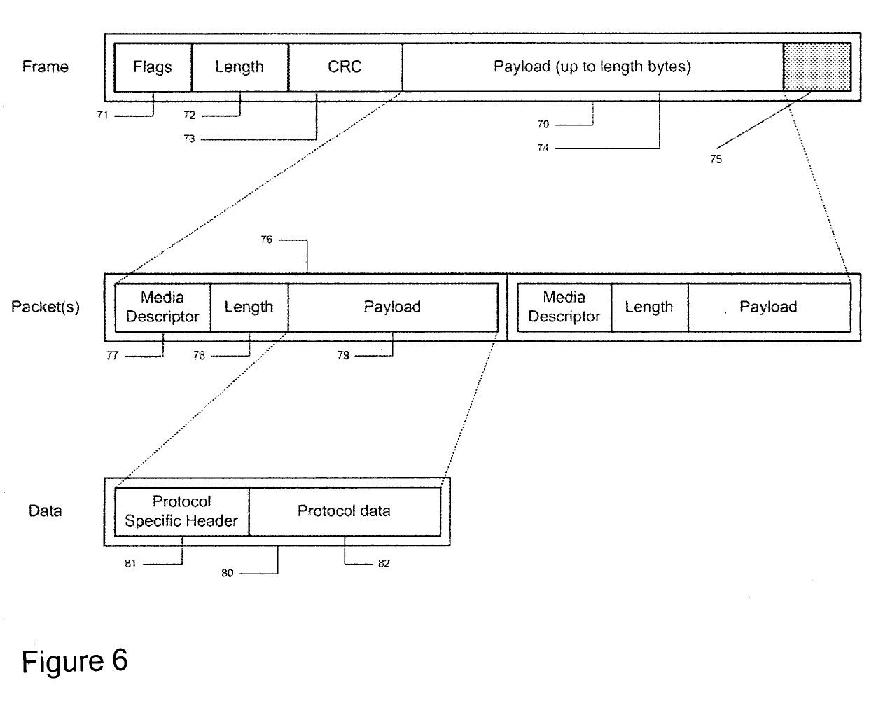

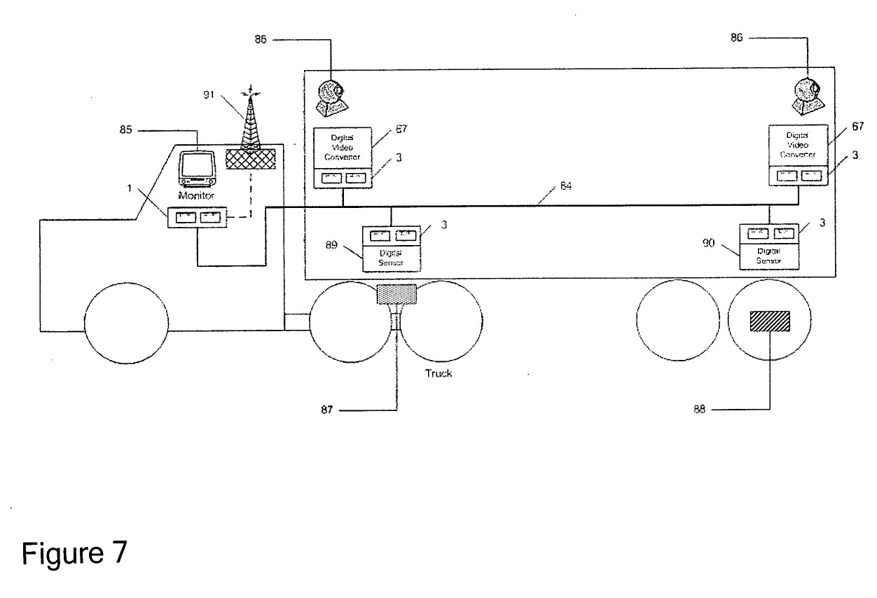

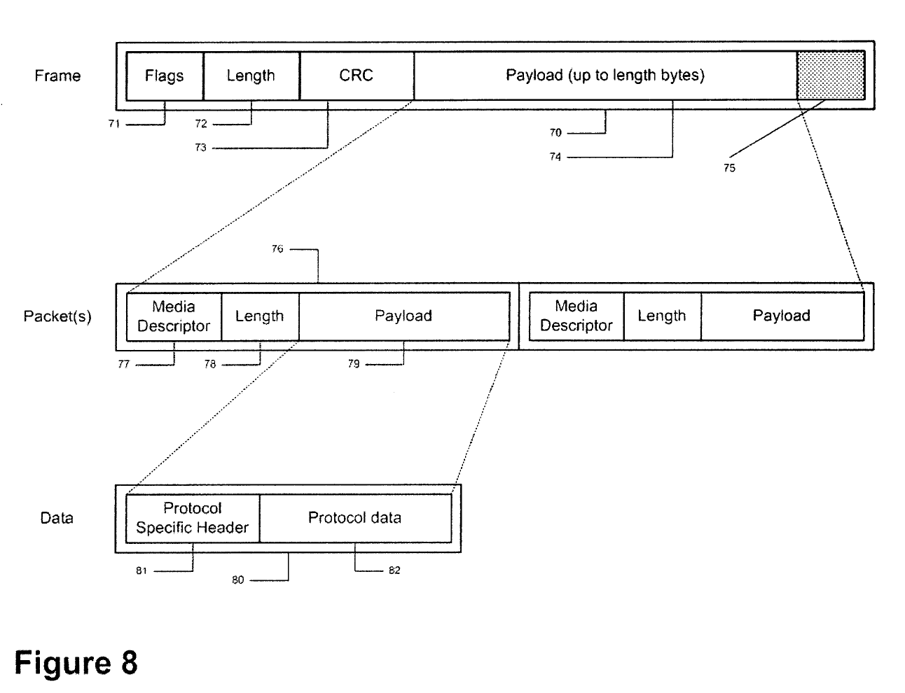

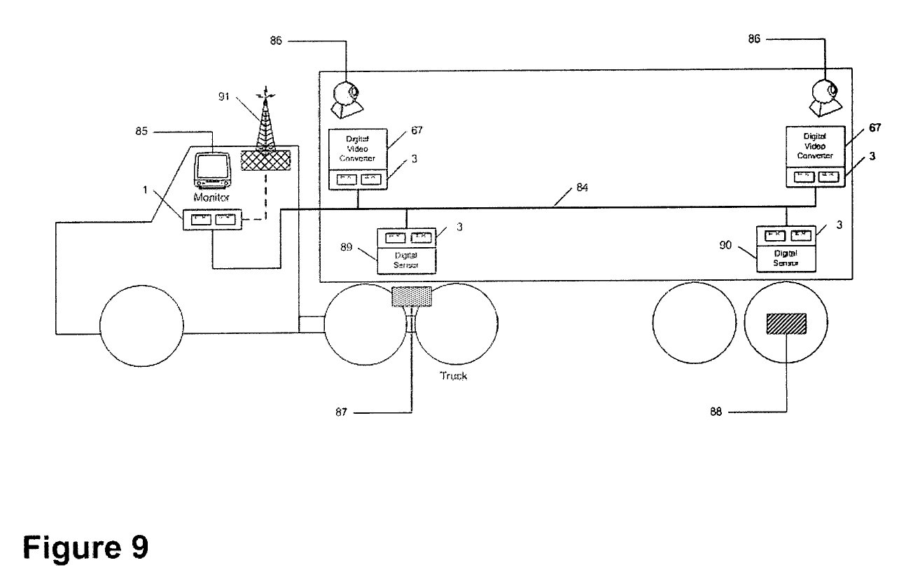

The lowest unit of the digital transmission is a frame 70. The maximum frame size is defined by the time duration of a time slot. Referring to FIG. 6, the frame of the preferred embodiment comprises:
a. a flags field 71 that contains MAC control information including a destination address,
b. a length field 72 that specifies the number of valid octets in a payload,
c. a cyclic redundancy check (CRC) field 73 that contains a CRC block calculated over the payload block before transmission,
d. a payload 74, and
e. possibly some unused frame bytes 75.

The payload of each frame contains one or more packets 76.

The packet format 76 of the preferred embodiment is shown in FIG. 6 and is defined as follows:
a. a media descriptor field 77 that is used to classify the type of packet, and
b. a length field 78, which is the number of octets in the payload, following the packet's payload 79.

Typically, the packet payloads 79 contain a protocol specific header 81 and data 82.

The media descriptor field 77 contains information about the type of protocol that was used at the user to network interface (UNI) ( ) to form the packet 76. This allows various forwarding hardware to provide a better quality of service based of the content type carried in the payload 79. For example, one of the pre-defined media descriptor values is used to indicate a MAC supervisory packet.

The advantage of using this format is that it allows the PLC to carry a virtually limitless set of media formats. These include, but not limited to, Internet Protocol (IP) data, automatic meter reading (AMR) information, digitized voice and phone services, digital television signal, digital video and surveillance streams.

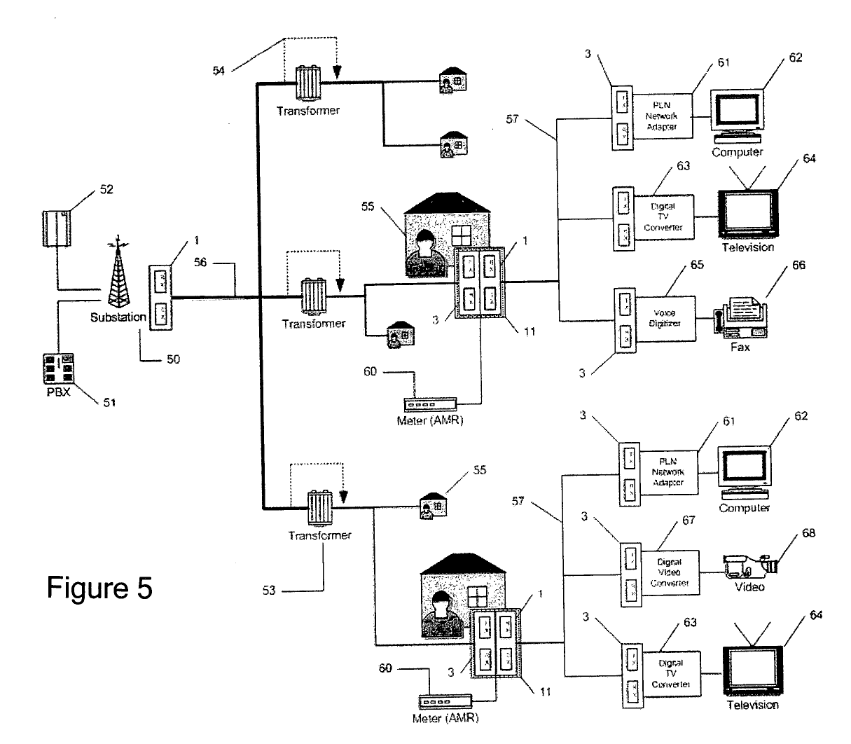

Referring now to FIG. 5, there is shown a diagram of a typical implementation of a PLC. To support one or more of media service types, the head-end unit 1 located at the power line substation 50 is connected to a service provider's uplink. The type of the uplink and the protocol used depends on the type of service being supported. For example, for IP networks, the substation would typically be equipped with a high-speed fiber data uplink 52, such as SONET or Gigabit-Ethernet. Similarly, to support digital phone and voice communication systems, the substation must would include a digital interface to a PBX or SS7 switch 51.

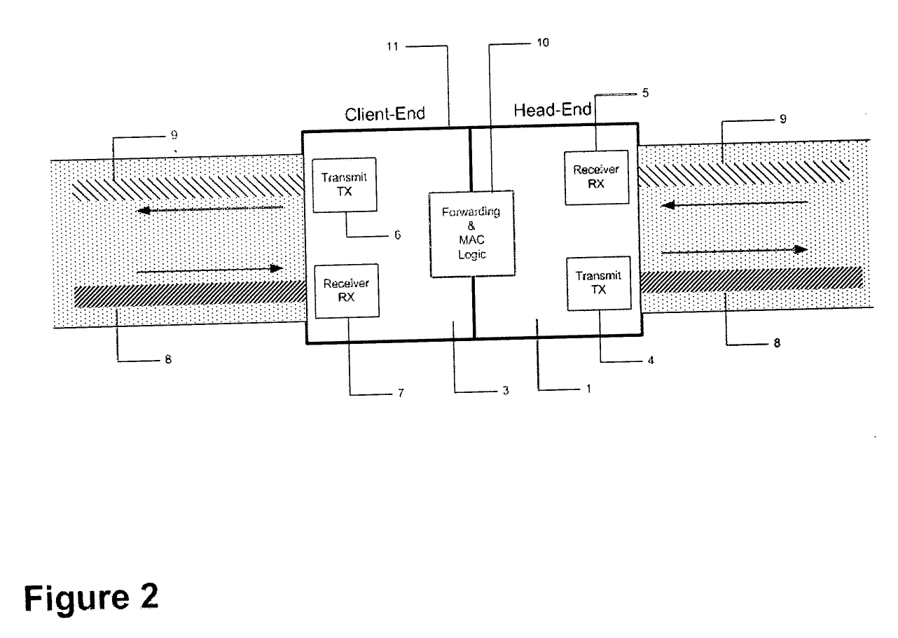

The signal from the uplinks is transmitted over the power line grid 56 from the head-end unit to the client-end units 3 located at each residential or commercial end-user's premises 55. It is worth noting here, that the signals are passed through 54 any transformer 53 located between the substation and the customer premise equipment (CPE) without regeneration. The CPE is actually a hybrid network element 11, (see FIG. 2) which includes a client-end unit 3 for the head-end 1, MAC logic 10, and a head-end unit 1 for the LPLN 57 inside of the customer premise.

The LPLN 57 at the customer premise comprises a single head-end unit 1, which is typically co-located with the power meter and an optional automatic meter reading (ANR) device 60, and one or more client-end units 3. The client-end units 3 contain media-based adapters which enable a large variety of hardware to communicate over the power line communication network. For example, the PLN network adapter 61 allows personal computers 62 (PCs) to be connected to the LPLN 57. Other adapters may include: digital television converters 63, which allow the reception of high-quality digital TV or cable service for television sets 64, voice digitizer and phone interface 65, which provides digital quality voice communication; facsimiles 66, video converters 67, which allow cameras and other surveillance devices 68 to use the power line communication network.

Notwithstanding the example applications described above, the power line communication system described in this application can also be used over DC power lines. One example of this use is in the area of transportation, where various vehicles, such as trucks, automobiles, trains, are equipped with a variety of sensory equipment, such as break 89 and tire pressure 90 sensors for monitoring brakes 87 and tires 88.

The analog signals captured by the sensors are digitized by the sensory input digitizer(s) 89 and 90, and through their associated client end units 3, the digital signal is transmitted over the DC power line 84 toward the head-end unit 1. Similarly, cameras and other image capture equipment may be attached to the vehicles, for example to assist the driver backing up. The analog signal converted by the camera 86 is digitized by the digital video converter unit 67, and its output is transmitted by the client-end unit 3 through the DC power line 84 toward the head-end unit 1. All data is transmitted to a central monitoring and recording unit 85 which is located at the head-end unit. It is foreseeable that the input data collected by the head-end unit 1 may be transmitted to a centralized operation center or other vehicles in the area. This information is typically transmitted over wireless and/or satellite communication channels.

Changes can be made to the embodiments described above without departing from the broad inventive concept thereof. The present invention is thus not limited to the particular embodiments disclosed, but is intended to cover modifications within the spirit and scope of the present invention.

1-24. Canceled

25. A communication system for communicating information over a power line grid comprising:
a first head-end unit connected at a distant end to the power line grid; and
one or more first hybrid units connected to the power line grid at a customer premises, said one or more hybrid units including:
a first client-end unit adapted to communicating with the first head end unit, and
a second head-end unit adapted to communicating with the first client-end unit and with one or more second client-end units.

26. The communication system of claim 1, wherein one or more of the second client-end units also includes a third head-end unit, each third head-end unit being adapted to communicate with the one or more second client-end unit and one or more third client-end units.

27. The communication system of claim 1, wherein each head-end unit communicates with one or more associated client-end units over: (1) a logical half-duplex downstream communication channel, whereby a carrier frequency of the head-end unit's transmitter output is matched by the receive frequency of each of the client-end units associated with the head-end unit, and (2) a logical half-duplex upstream communication channel, in which a carrier frequency of each of the client-end units' transmitter output is matched with the receive frequency of the head-end unit, the upstream and downstream channels associated with the head-end unit and the associated client-end units forming a sub-network.

28. The communication system of claim 3 wherein the carrier frequencies of each of the downstream and upstream channels operating on the wide area power line network are mutually exclusive.

29. The communication system of claim 4, wherein the system comprises a plurality of subnets, the frequency bands of the upstream and the downstream channels of the plurality of sub-networks being mutually exclusive.

30. The communication system of claim 3, wherein the bandwidth of the downstream communication channel is substantially identical to the bandwidth of the upstream communication channel.

31. The communication system of claim 3 wherein the upstream and the downstream channels each utilize a frame format comprising:
a flag field including a destination address,
a length field, which identifies the number of octets in the payload of the frame,
a media selector field, which identifies the type of payload,
a cyclic redundancy check (CRC) field, which contains the CRC value calculated over a remaining portion of the frame, and
a payload field including an arbitrary sequence of data.

32. The communication system of claim 7, wherein each client-end unit examines the destination address of the data frame received from the head-unit, and (1) if the destination hardware address matches with its own hardware address, the frame is scheduled for processing, and (2) if the hardware address of the client-end unit is not found, the frame is discarded.

33. The communication system of claim 3, wherein each upstream communication channel is divided into one or more time slots.

34. The communication system of claim 9, wherein time slot resources in a head-end are allocated to the associated client-end units by a subscription based allocation scheme, wherein any unallocated resources are temporarily allocated to the associated client-end units with the constraints that the unallocated resources may be revoked at any time, without notice by the head-end unit.

35. The communication system of claim 9, wherein every associated client-end device receives an equal share of the time slot resources.

36. The communication system of claim 9, wherein time slot resources are dynamically reassigned when a new client-end unit is inserted into the network or a client-end unit which has been assigned time slot resources is deactivated.

37. The communication system of claim 9, further including a medium access control sub-system within each head-end unit, the medium access control sub-system periodically broadcasting a time slot allocation signal in a predetermined one of the time slots, wherein if an individual one of the client-end unit detects the time slot allocation signal having an address of the individual client-end unit, the individual client-end unit may transmit in an allocated time slot, and if the individual one of the client-end units does not detect the allocated time slot signal with the address of the individual client-end unit, the individual client-end unit may not transmit in the allocated time slot.

38. The communication system of claim 9, further including a medium access control sub-system within each head-end unit, the medium access control sub-system periodically providing a registration time slot adapted for receiving registration signals from the client-end units, wherein upon receipt of a registration signal from an individual one of the client-end units, the medium access control subsystem allocates a time slot to the individual client end-unit by including the address of the individual client-end unit in the next broadcasted time slot allocation signal.

39. The communication system of claim 3, wherein the head-end unit broadcasts identical downstream data to all client-end units on the same logical sub-network.

40. A method of adding a client-end unit to the communication system of claim 1, comprising the steps of:
a. detecting a supervisory packet transmitted from a head-end unit;
b. searching the supervisory packet for an address of the client end unit;
c. storing a slot allocation in the client end unit if the address of the client end unit is found in the supervisory packet; and
d. sending a registration message to the head unit if the address of the client-end unit is not found in the supervisory packet, or within a subsequently transmitted supervisory packet within a predetermined time period, whereby upon receiving the registration message, the head-end unit adds the address of the client-end unit and a slot allocation for the client-end unit to a later transmitted supervisory packet.

41. A method of detecting an inactive client-end unit on the communication system of claim 1, comprising the steps of:
a. examining each upstream time slot to determine if the transmission contains valid data;
b. incrementing a missing slot counter if the time slot does not contain valid data;
c. marking the client-end unit “down” if a maximum count in the missing slot counter is exceeded, removing the client-end unit's resource allocation record from a time slot allocation table broadcast by the head-end unit 1; and
d. allocating, if possible, the previously allocated time slots to other client-end units.

42. A method of reconfiguring a client-end unit connected to the communication system of claim 1, comprising the steps of:
a. detecting a supervisory packet transmitted from a head-end unit;
b. searching the supervisory packet for an address of the client-end unit;
c. storing a slot allocation in the client-end unit if the address of the client-end unit is found in the supervisory packet; and
d. ceasing transmission if the client-end unit fails to find its address after detecting a predetermined number of supervisory packets.
